(19) United States
(12) Patent Application Publication
(10) Pub. No.: US 2025/0379588 A1
(43) Pub. Date: Dec. 11, 2025

(54) DEVICE AND METHOD FOR ENCODING PIPELINE ADC

(71) Applicants: Chongqing GigaChip Technology Co., Ltd., Chongqing (CN); NO.24 RESEARCH INSTITUTE OF CHINA ELECTRONICS TECHNOLOGY GROUP CORPORATION, Chongqing (CN)

(72) Inventors: Daiguo XU, Chongqing (CN); Dongbing FU, Chongqing (CN); Song YANG, Chongqing (CN); Xuebing LI, Chongqing (CN); Xingbing WU, Chongqing (CN); Jianan WANG, Chongqing (CN); Guangbing CHEN, Chongqing (CN); Zhou YU, Chongqing (CN); Zhengping ZHANG, Chongqing (CN); Can ZHU, Chongqing (CN); Lu LIU, Chongqing (CN); Haiyang YU, Chongqing (CN)

(73) Assignees: Chongqing GigaChip Technology Co., Ltd., Chongqing (CN); NO.24 RESEARCH INSTITUTE OF CHINA ELECTRONICS TECH, Chongqing (CN)

(21) Appl. No.: 19/302,090

(22) Filed: Aug. 18, 2025

Related U.S. Application Data
(63) Continuation of application No. PCT/CN2024/107575, filed on Jul. 25, 2024.

(30) Foreign Application Priority Data
Apr. 24, 2024 (CN) 202410494127.7

(51) Int. Cl. H03M 1/36; H03K 19/20

(52) U.S. Cl. CPC H03M 1/36; H03K 19/20

(57) ABSTRACT

A device for encoding pipeline ADC includes: a comparator circuit connected to differential input signals and outputting a plurality of comparison results; a first encoding circuit, performing a pairwise NAND operation on the plurality of comparison results to output a plurality of NAND operation results, and outputting a first signal or/and a second signal based on the plurality of NAND operation results and the level of a first selection signal under the control of a clock signal; an encoding control circuit, generating a second selection signal based on the occurrence probability of each signal in a first digital code, receiving a third signal and a fourth signal and outputting a first selection signal according to the level of the second selection signal; a second encoding circuit, outputting a second digital code according to the first digital code under the control of switching of a plurality of switching transistors.

### CROSS REFERENCE TO RELATED APPLICATION

The present disclosure is a continuation application of International Patent Application No. PCT/CN2024/107575, filed on Jul. 25, 2024, which claiming the priority to Chinese Application No. 202410494127.7 filed on Apr. 24, 2024, the contents of all of which are incorporated herein by reference in their entirety for all purposes.

### TECHNICAL FIELD

The present application relates to the field of analog integrated circuit technology, and in particular to a device and a method for encoding pipeline ADC.

### BACKGROUND

In a conventional pipeline ADC, the sub-ADC in a single-stage pipeline is usually a flash-structure ADC. There are multiple comparators in the flash-structure ADC. When the flash-structure ADC is working, multiple comparators are enabled by the same clock and compare the same input signal with different reference voltages at the same time. After the comparison is completed, the output results of the multiple comparators are input into the encoding circuit and encoded by the encoding circuit. After the encoding is completed, the digital code is input into the digital circuit, and after the output digital code of the remaining stages is added in a staggered way, the digital code of the final conversion result of the ADC is output.

### SUMMARY

In one aspect, the present application provides a device for encoding pipeline ADC. The device includes:
a comparator circuit, wherein an input end of the comparator circuit is connected to differential input signals and the comparator circuit outputs a plurality of comparison results;
a first encoding circuit, connected to the comparator circuit, performing a pairwise NAND operation on the plurality of comparison results to output a plurality of NAND operation results, and outputting one or more first signals or/and one or more second signals based on the plurality of NAND operation results and a level of the first selection signal under the control of a clock signal; wherein the one or more first signals or/and the one or more second signals form a first digital code;
an encoding control circuit, connected to an output end of the first encoding circuit, generating a second selection signal based on an occurrence probability of each signal in the first digital code, receiving a third signal and a fourth signal, and outputting the first selection signal according to a level of the second selection signal, wherein the third signal is generated by a random number generator, the fourth signal is a preset level signal; and
a second encoding circuit, wherein an input end of the second encoding circuit is connected to an output end of the first encoding circuit, and the second encoding circuit outputs a second digital code according to the first digital code under a switch control of a plurality of switching transistors.

In an embodiment of the present application, the comparator circuit includes a plurality of comparators arranged in parallel, the first encoding circuit includes a plurality of encoding modules, and each of the encoding modules includes:
a NAND gate, wherein input ends of the NAND gate are connected to the comparison results, and the comparison results are output through two adjacent output ends of two adjacent comparators, one output end of the NAND gate outputs a positive output signal, and the other output end of the NAND gate outputs a negative output signal;
a D flip-flop, wherein a signal input end of the D flip-flop is connected to an output end of the NAND gate, and a first output end of the D flip-flop outputs the first signal, and a second output end of the D flip-flop outputs the second signal; and
a first selection module, wherein a first input end of the first selection module is connected to the first signal, a second input end of the first selection module is connected to the second signal, a control end of the first selection module is connected to the first selection signal, and the first selection module outputs the first signal or the second signal according to the level of the first selection signal.

In an embodiment of the present application, when the first selection signal is at a high level, the first selection module uses the first signal as an output signal; and when the first selection signal is at a low level, the first selection module uses the second signal as the output signal.

In an embodiment of the present application, the encoding control circuit includes:
a random number generator, generating and outputting a random number sequence as the third signal;
a plurality of second selection modules, wherein an input end of the second selection module is connected to an output end of the random number generator, the second selection module is connected to the third signal and a fourth signal, a control end of the second selection module is connected to the second selection signal, the second selection module outputs the first selection signal according to the level of the second selection signal; and the plurality of second selection modules correspond one to one with the plurality of first selection modules; and
a code density judgment module, wherein an input end of the code density judgment module is connected to an output end of the first selection module to receive the first digital code, and the code density judgment module outputs the second selection signal according to an occurrence probability of each signal in the first digital code.

In an embodiment of the present application, when the second selection signal is at a high level, the second selection module uses the third signal as an output signal; and when the second selection signal is at a low level, the second selection module uses the fourth signal as the output signal.

In an embodiment of the present application, the fourth signal is 0.

In an embodiment of the present application, the second encoding circuit includes:
a first encoding module, wherein an input end of the first encoding module is connected to the first digital code, and the first encoding module outputs a fifth signal according to the first digital code under a switch control of a plurality of switching transistors; and
a second encoding module, wherein an input end of the second encoding module is connected to the first digital code, and the second encoding module outputs a sixth signal according to the first digital code under a switch control of a plurality of switching transistors.

In an embodiment of the present application, the first encoding module includes: a first MOS transistor, a second MOS transistor, a third MOS transistor, a fourth MOS transistor, a fifth MOS transistor, a first resistor, and a first NOT gate; a source of the first MOS transistor is connected to a first voltage, a drain of the first MOS transistor is connected to a source of the second MOS transistor, a drain of the second MOS transistor is connected to a drain of the third MOS transistor and forms a first connection node, a source of the third MOS transistor is connected to a second voltage; a source of the fourth MOS transistor is connected to the first voltage, a drain of the fourth MOS transistor is connected to a source of the fifth MOS transistor, a drain of the fifth MOS transistor, one end of the first resistor, and an input end of the first NOT gate are respectively connected to the first connection node, the other end of the first resistor is connected to the second voltage, an output end of the first NOT gate outputs a fifth signal; and a gate of the first MOS transistor, a gate of the third MOS transistor, and a gate of the fourth MOS transistor are respectively connected to an enable signal, and a gate of the second MOS transistor and a gate of the fifth MOS transistor are connected to the first digital code.

In an embodiment of the present application, the second encoding module includes: a sixth MOS transistor, a seventh MOS transistor, an eighth MOS transistor, a nineth MOS transistor, a tenth MOS transistor, a second resistor, and a second NOT gate; a source of the sixth MOS transistor is connected to the second voltage, a drain of the sixth MOS transistor is connected to a source of the seventh MOS transistor, a drain of the seventh MOS transistor is connected to a drain of the eighth MOS transistor and forms a second connection node, a source of the eighth MOS transistor is connected to the second voltage; a source of the ninth MOS transistor is connected to the first voltage, a drain of the ninth MOS transistor is connected to a source of the tenth MOS transistor, a drain of the tenth MOS transistor, one end of the second resistor, and an input end of the second NOT gate are respectively connected to the second connection node, the other end of the second resistor is connected to the second voltage, an output end of the second NOT gate outputs a sixth signal; and a gate of the sixth MOS transistor, a gate of the eighth MOS transistor, and a gate of the ninth MOS transistor are respectively connected to an enable signal, and a gate of the seventh MOS transistor and a gate of the tenth MOS transistor are connected to the first digital code.

In another aspect, the present application provides a method for encoding pipeline ADC, the encoding method includes:
receiving differential input signals to output a plurality of comparison results;
performing a pairwise NAND operation on the plurality of comparison results to output a plurality of NAND operation results, and outputting one or more first signals or/and one or more second signals based on the plurality of NAND operation results and a level of a first selection signal under the control of a clock signal; wherein the one or more first signals or/and one or more second signals form a first digital code;
generating a second selection signal based on an occurrence probability of each signal in the first digital code, and receiving a third signal and a fourth signal and outputting the first selection signal according to a level of the second selection signal, wherein the third signal is generated by a random number generator; and
outputting a second digital code according to the first digital code under the control of switching of a plurality of switching transistors.

It should be understood that the foregoing general description and the following detailed description are exemplary and explanatory only and are not restrictive of the present application.

### BRIEF DESCRIPTION OF DRAWINGS

In order to more clearly illustrate the technical solutions of the embodiments of the present application, the drawings required for use in the description of the embodiments of the present application will be briefly introduced below. Obviously, the drawings described below are only some embodiments of the present application. For ordinary technicians in this field, other drawings can be obtained based on these drawings without paying any creative labor.

FIG. 1 is a schematic diagram of a single-stage flash ADC in a pipeline ADC in the prior art;

FIG. 2 is a schematic diagram of a single-stage transfer function of a pipeline ADC in the prior art;

FIG. 3 is a schematic diagram of a device for encoding pipeline ADC according to an embodiment of the present application;

FIG. 4A to FIG. 4C are circuit diagrams of specific implementations of a device for encoding pipeline ADC according to an embodiment of the present application;

FIG. 5A to FIG. 5E are schematic diagrams of comparator offset voltage and B0-B3 coding output according to an embodiment of the present application;

FIG. 6 is a flow chart of a coding method for pipeline ADC coding according to an embodiment of the present application.

### DESCRIPTION OF EMBODIMENTS

The following describes the embodiments of the present application by specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application. It should be noted that the following embodiments and features in the embodiments can be combined with each other without conflict.

It should be noted that the illustrations provided in the following embodiments are only schematic illustrations of the basic concept of the present application, and thus the drawings only show components related to the present application rather than being drawn according to the number, shape, and size of components in actual implementation. In actual implementation, the type, quantity, and scale of each component may be changed arbitrarily, and the component layout may also be more complicated.

Although the terms “first”, “second”, “A”, “B”, etc. may be used herein to describe various elements, these elements should not be limited by these terms and are only used to distinguish one element from another. For example, a first element may be referred to as a second element, and similarly, a second element may be referred to as a first element without departing from the scope of the following technology. The term “and/or” includes a combination of multiple related items or any item in the multiple related items.

As used herein, unless the context indicates otherwise, the singular form is intended to include the plural form, and it will be understood that the term “comprising” means the presence of stated features, quantities, steps, operations, elements, or combinations thereof, but does not exclude the presence or addition of one or more other features, quantities, steps, operations, elements, components, or combinations thereof.

Before describing the drawings in detail, it is intended to clarify that the division of components in this specification is divided only by the main function of each component. That is, two or more components to be described below can be combined into one component, or can be divided into two or more components according to more detailed functions. In addition to the main function of the component, each component to be described below can also perform some or all of the functions of other components, and some of the main functions of each component can be exclusively performed by other components.

Since pipeline ADC can achieve a good compromise between speed and accuracy, it has become an important structure of ADC and is widely used in fields such as radar, satellite positioning, and sensors. In a conventional pipeline ADC, the sub-ADC in a single-stage pipeline is usually a flash ADC. There are multiple comparators in the flash-structure ADC. When the flash-structure ADC is working, the multiple comparators are enabled by the same clock and compare the same input signal with different reference voltages at the same time. After the comparison is completed, the output results of the multiple comparators are input into the encoding circuit and encoded by the encoding circuit. After the encoding is completed, the digital code is input into the digital circuit, and after the output digital code of the remaining stages is offset and added, the digital code of the final conversion result of the ADC is output. Since there is an offset voltage between multiple comparators in the flash-structure ADC, the output digital code of the encoding circuit is erroneous, which ultimately affects the accuracy of the entire ADC. Therefore, a correction method is proposed for the comparator offset voltage. The traditional correction method is the correction method in the analog domain, that is, multiple correction capacitors are connected to the input of the comparator. After the flash ADC is powered on, the offset voltage correction mode is set. By adjusting the capacitance of the correction capacitor at each comparator input, the offset voltage of the comparator is adjusted, and finally, the offset voltage of the comparator meets the accuracy requirement.

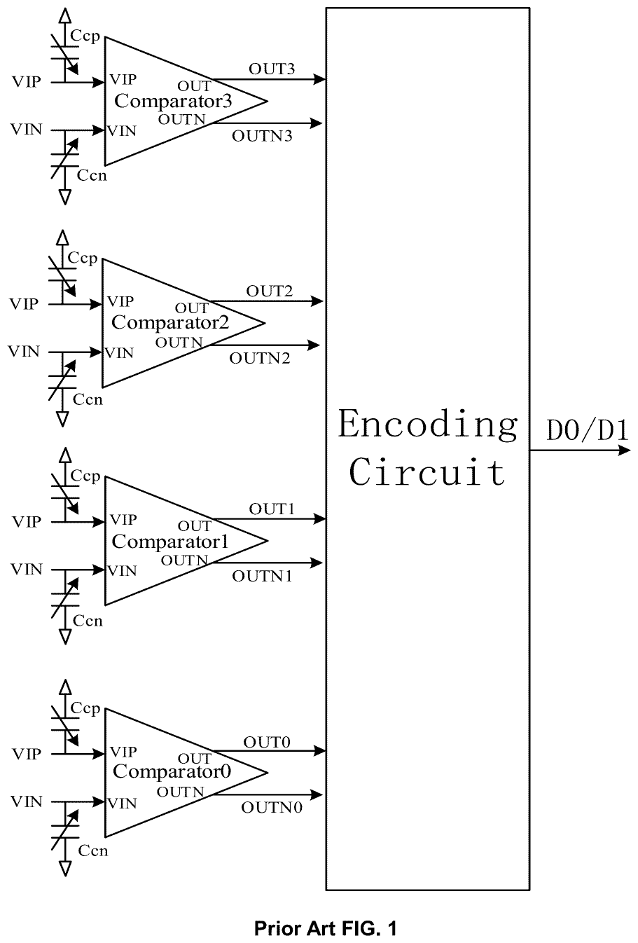

The following is an analysis of the advantages and disadvantages of the existing comparator offset voltage correction method in the conventional pipeline ADC design. Taking the single-stage output 2-bit digital code as an example, the schematic diagram of the single-stage flash ADC in the pipeline ADC is shown in FIG. 1. The single-stage ADC includes four comparators (Comparator 0 to Comparator 3), comparator input trimming capacitors (Ccp and Con), and an encoding circuit. The final output code of the encoding circuit is D1/D0. Flash ADC includes comparator 0 to comparator 3. The input of each comparator is connected to the input signal VIP and VIN respectively. For the sake of simplicity, the reference voltage of each comparator input is not shown here. The inputs of the four comparators are connected to the offset correction capacitors Ccp and Con respectively. The positive output signals of the four comparators are OUT0 to OUT3, and the negative output signals of the four comparators are OUTN0 to OUTN3. After the positive and negative output signals of the four comparators are input to the encoding circuit, the 2-bit code D0/D1 is finally generated. When the comparator is in the offset voltage correction mode, the outputs of the four comparators generate corresponding output signals when specific input signals are input. The digital circuit judges the offset situation of each comparator by reading the output signals of the four comparators, and then the correction capacitors Ccp and Con at the input of each comparator are adjusted through a digital control signal. When the capacitances of the correction capacitors Ccp and Con at the inputs of the comparator change, the offset voltage of the comparator is compensated, thereby realizing the correction function of the offset voltage of the comparator.

In a conventional pipeline ADC, the following problems exist in the offset voltage correction of the flash ADC. (1) Since a special offset voltage correction mode is required, in this mode, the offset voltages of multiple comparators are corrected, which makes the circuit operation timing more complicated. (2) Since the correction method in the analog domain is adopted, it is necessary to introduce the signal in the digital domain into the analog domain. When the number of comparators is large, it will lead to complex layout routing, and also introduce non-ideal jitter and noise in the digital domain, reducing the accuracy of the analog circuit. (3) Since the trimming capacitor is introduced at the input of the comparator, the load of the sampling network is increased, the input bandwidth is reduced, and the circuit area and complexity are increased.

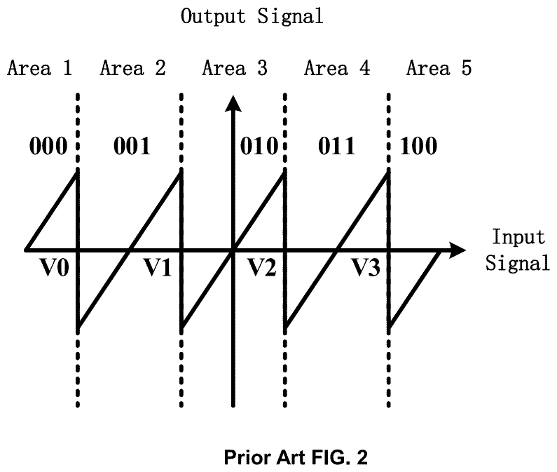

The schematic diagram of the single-stage transfer function of the pipeline ADC is shown in FIG. 2, where V0 to V3 are the threshold voltages of the four comparators respectively, and the 3-digit codes correspond to the output codes of the corresponding intervals. Since the inter-stage redundant bit technology is used in the design of the pipeline ADC, as long as the offset of the comparator does not exceed the threshold voltage of the adjacent interval, the final digital code will not be wrong. For example, as long as the fluctuation of the comparator threshold voltage V2 in FIG. 2 is between the threshold voltages V1 and V3 of its two adjacent comparators, the inter-stage redundant bit technology of the pipeline can correct the above offset. When the offset of the comparator exceeds the threshold voltage of the adjacent interval, the inter-stage redundant bit technology cannot effectively correct the offset voltage. Based on the shortcomings of the conventional comparator offset voltage correction method in the existing pipeline ADC, the present application proposes a device for encoding pipeline ADC that uses digital correction to correct the offset of the comparator. The device can correct the offset of the comparator when the fluctuation of V2 exceeds out of the interval of V1 and V3.

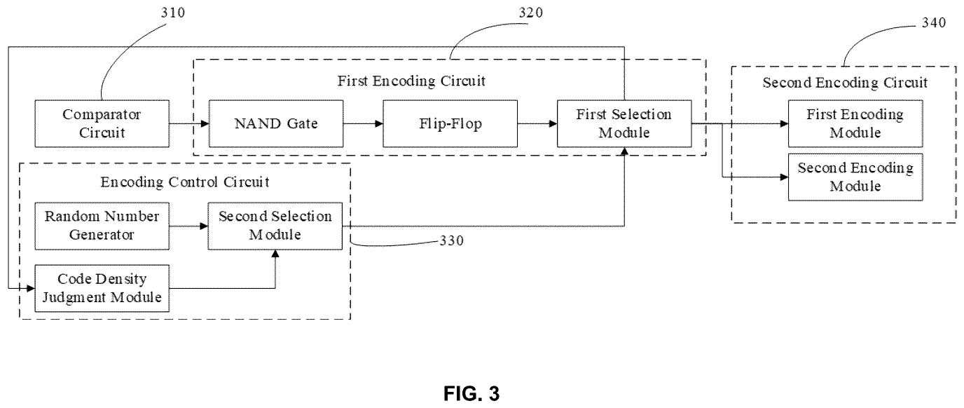

Please refer to FIG. 3, which is a schematic diagram of a device for encoding pipeline ADC according to an embodiment of the present application. As shown in FIG. 3, the device for encoding pipeline ADC includes:
a comparator circuit 310, wherein the input end of the comparator circuit 310 is connected to a differential input signal, and the comparator circuit 310 outputs a plurality of comparison results;
a first encoding circuit 320, wherein the first encoding circuit 320 is connected to the comparator circuit, performs a pairwise NAND operation on the plurality of comparison results, outputs a plurality of NAND operation results, and outputs one or more first signals or/and one or more second signals based on the plurality of NAND operation results and the level of a first selection signal under the control of a clock signal; the one or more first signals or/and one or more second signals constitute a first digital code;
an encoding control circuit 330, wherein the encoding control circuit is connected to an output end of the first encoding circuit, generates a second selection signal based on the occurrence probability of each signal in the first digital code, receives a third signal, and a fourth signal, and outputs the first selection signal according to the level of the second selection signal; the third signal is generated by a random number generator; and
a second encoding circuit 340, wherein the second encoding circuit has an input end connected to the output end of the first encoding circuit, and outputs a second digital code according to the first digital code under the control of switching of a plurality of switching transistors.

The following is a detailed description of each component module, taking a single-stage outputting a 2-bit digital code as an example.

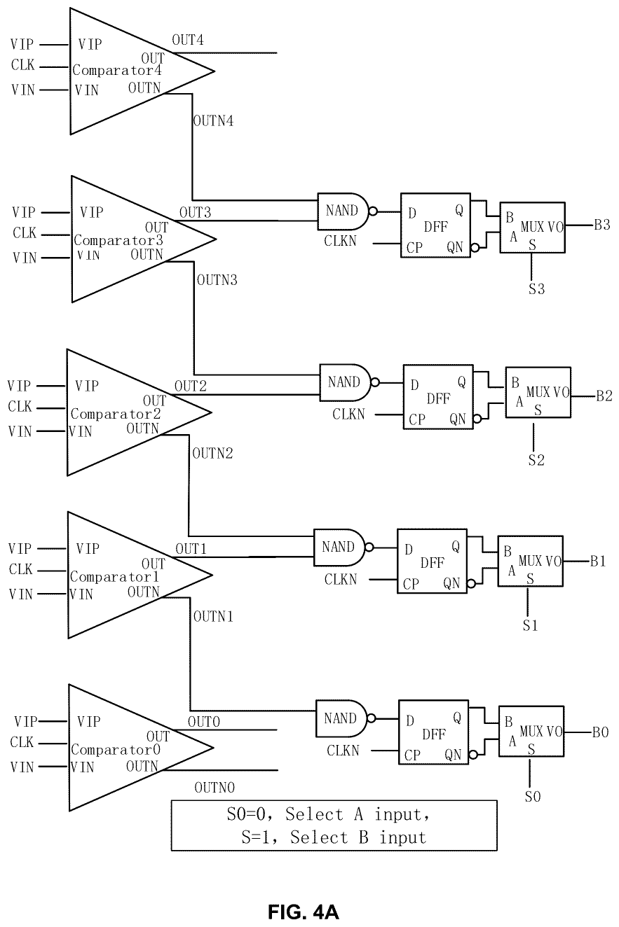

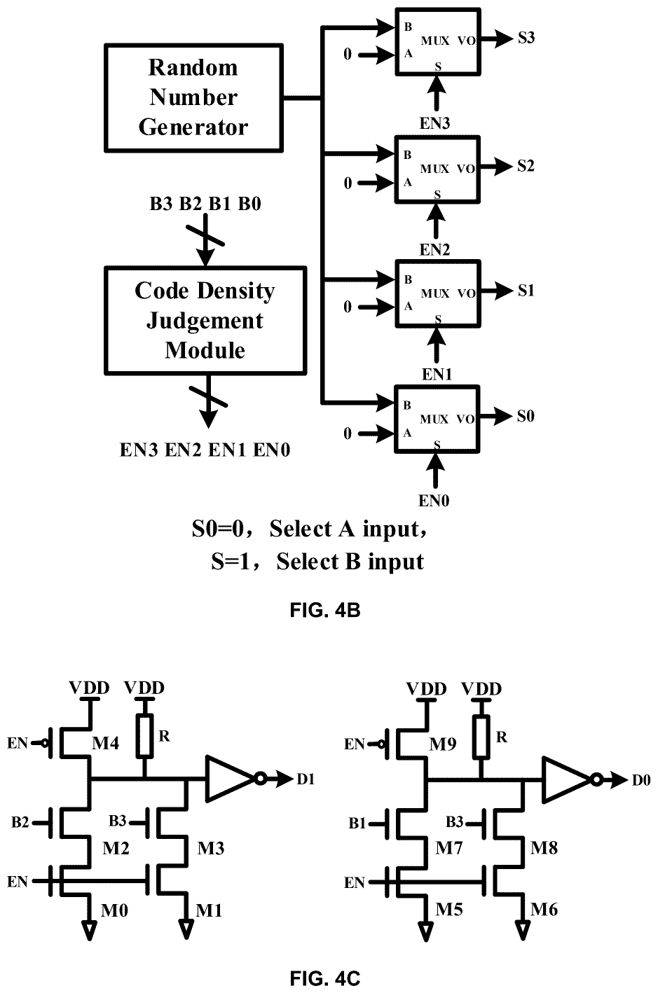

The comparator circuit includes a plurality of comparators arranged in parallel, as shown in FIG. 4A. The comparator circuit has five comparators, namely, comparator 0, comparator 1, comparator 2, comparator 3, and comparator 4. Each comparator receives differential input signals VIP and VIN. For simplicity, the reference voltage at the input of each comparator is not shown in the figure. Each comparator includes two output ends, i.e., a positive output end and a negative output end. The positive output end outputs a signal OUTi (i=0, 1, 2, 3, 4), and the negative output end outputs a signal OUTNi (i=0, 1, 2, 3, 4). The CLK signal is the clock signal of the comparator. When CLK is at a low level, the comparator is in a reset state, and the D flip-flop DFF latches the output signal of the comparator in the previous comparator cycle. When CLK is at a high level, the comparator is in a comparison state to compare the input signal.

In a specific implementation, the first encoding circuit 320 includes a plurality of encoding modules, each encoding module includes:
a NAND gate NAND, wherein an input end of the NAND gate is connected to the comparison result, the comparison result is output through two adjacent output ends of two adjacent comparators, one of the two adjacent output ends outputs a positive output signal, and the other of the two adjacent output ends outputs a negative output signal; and
a D flip-flop DFF, wherein a signal input end of the D flip-flop is connected to an output end of the NAND gate, a first output end of the D flip-flop outputs a first signal, and a second output end of the D flip-flop outputs a second signal; and
a first selection module MUX, wherein a first input end of the first selection module is connected to a first signal, a second input end of the first selection module is connected to a second signal, a control end of the first selection module is connected to a first selection signal, and the first selection module outputs the first signal or the second signal according to the level of the first selection signal.

The comparator 4 and the comparator 3 are two adjacent comparators, and the negative output end of the comparator 4 and the positive output end of the comparator 3 are two adjacent output ends; the NAND gate includes two input ends connected to the comparison results output by the comparators.

As shown in FIG. 4A, one of the input ends of the first NAND gate NAND is connected to the negative output end OUT4 of the comparator 4, and the other input end of the first NAND gate NAND is connected to the positive output end OUT3 of the comparator 3. The D flip-flop DFF includes a signal input end D, a clock end CP, a first output end Q, and a second output end QN. The signal input end D is connected to the output end of the NAND gate NAND. The clock end CP is connected to the clock signal CLKN, CLKN is the inverted signal of CLK. The first output end Q outputs the first signal, and the second output end QN outputs the second signal. The first selection module MUX includes a control end S, a first input end B, a second input end A, and an output end VO. The first input end B is connected to a first output end Q of the D flip-flop DFF, and the second input end A is connected to the second output end QN of the D flip-flop DFF. The control end is connected to the first selection signal, and the first signal or the second signal is output according to the level of the first selection signal. When the first selection signal is at a low level, the first selection module MUX selects the value of the second input end A and outputs the value of the second input end A at the output end VO, and when the first selection signal is at a high level, the first selection module MUX selects the value of the first input end B and outputs the value of the first input end B at the output end VO, that is, when the first selection signal is at a low level, the output end VO outputs the second signal, and when the first selection signal is at a high level, the output end VO outputs the first signal. The control signals Si (i=0, 1, 2, 3) control the corresponding MUX modules respectively.

It can be seen that after the differential input signals are received by the comparator 0 to the comparator 5 and processed by the NAND gate, the D flip-flop, and the first selection module, the first digital code B0 to B3 are output.

Please refer to FIG. 4B, which is a circuit diagram of the encoding control circuit in this embodiment. In FIG. 4B, the encoding control circuit 330 includes:
a random number generator, which generates and outputs a third signal as a random number sequence;
a plurality of second selection modules, wherein input ends of each second selection module are connected to an output end of the random number generator and connected to the third signal and a fourth signal, a control end of each second selection module is connected to a second selection signal and outputs the first selection signal according to the level of the second selection signal; the plurality of second selection modules correspond one to one with the plurality of first selection modules; and
a code density judgment module, wherein an input end of the code density judgment module is connected to the output end of the first selection module and connected to the first digital code, and the code density judgment module outputs a second selection signal according to the occurrence probability of each signal in the first digital code.

In this embodiment, the number of the second selection modules is the same as the number of the first selection modules, each second selection module corresponds to a first selection module, and the output signal of the second selection module serves as the control signal of the first selection module.

As shown in FIG. 4B, the second selection module includes two input ends, a control end S, and an output end VO, wherein the first input end B is connected to the output end of the random number generator to receive data in the random number sequence, i.e., the third signal, and the second input end A is connected to the fourth signal. In an embodiment, the fourth signal is 0. The control end S and the output end of the code density judgment module are connected to the second selection signal, and the second selection module MUX outputs the third signal or the fourth signal according to the level of the second selection signal. Specifically, when the second selection signal is at a low level, the second selection module MUX selects the value of the second input end A to output it at the output end VO, and when the second selection signal is at a high level, the second selection module MUX selects the value of the first input end B to output it at the output end VO. In FIG. 4B, the random number generator uses the clock signal CLK of the comparator as a cycle to generate random high-level and low-level signals, which are input to the first input end B of the second selection module MUX of the subsequent stage, and the second input end A of the second selection module MUX is connected to 0, and the second selection module MUX outputs the control signal Si (i=0, 1, 2, 3), i.e., the first selection signal. In control diagram 4 (b), the second selection signal ENi (i=0, 1, 2, 3) controls each second selection module MUX respectively. FIG. 4B shows the code density judgment module, the function of which is to judge the density situation of each code in the digital codes B3 to B0 at the current stage. When the density of a code in the digital codes B3 to B0 is 0, the corresponding control signal EN3 to EN0 is generated.

Please refer to FIG. 4C, which is a circuit diagram of a second encoding circuit according to an embodiment of the present application. In FIG. 4C, the second encoding circuit includes:
a first encoding module, wherein an input end of the first encoding module is connected to the first digital code, and the first encoding module outputs a fifth signal according to the first digital code under the control of switching of a plurality of switching transistors; and
a second encoding module, wherein an input end of the second encoding module is connected to the first digital code, and the second encoding module outputs a sixth signal according to the first digital code under the control of switching of a plurality of switching transistors.

Specifically, the first encoding module includes: a first MOS transistor to a fifth MOS transistor, a first resistor, and a first NOT gate; the source of the first MOS transistor is connected to a first voltage, the drain of the first MOS transistor is connected to the source of the second MOS transistor, the drain of the second MOS transistor is connected to a drain of the third MOS transistor and forms a first connection node, and the source of the third MOS transistor is connected to a second voltage; the source of the fourth MOS transistor is connected to the first voltage, the drain of the fourth MOS transistor is connected to the source of the fifth MOS transistor, the drain of the fifth MOS transistor, one end of the first resistor, and an input end of the first NOT gate are respectively connected to the first connection node, the other end of the first resistor is connected to the second voltage, and the output end of the first NOT gate outputs a fifth signal, and the fifth signal is a part of the second digital code; the gate of the first MOS transistor, the gate of the third MOS transistor, and the gate of the fourth MOS transistor are respectively connected to an enable signal, and the gate of the second MOS transistor and the gate of the fifth MOS transistor are connected to the first digital code.

The second encoding module includes: a sixth MOS transistor to a tenth MOS transistor, a second resistor, and a second NOT gate; the source of the sixth MOS transistor is connected to the second voltage, the drain of the sixth MOS transistor is connected to the source of the seventh MOS transistor, the drain of the seventh MOS transistor is connected to the drain of the eighth MOS transistor and forms a second connection node, and the source of the eighth MOS transistor is connected to the second voltage; the source of the ninth MOS transistor is connected to the first voltage, the drain of the ninth MOS transistor is connected to the source of the tenth MOS transistor, the drain of the tenth MOS transistor, one end of the second resistor, and the input end of the second NOT gate are respectively connected to the second connection node, the other end of the second resistor is connected to the second voltage, and the output end of the second NOT gate outputs a sixth signal, and the sixth signal is another part of the second digital code; the gate of the sixth MOS transistor, the gate of the eighth MOS transistor, and the gate of the ninth MOS transistor are respectively connected to the enable signal, and the gate of the seventh MOS transistor and the gate of the tenth MOS transistor are connected to the first digital code.

Specifically, the first resistor and the second resistor are upper resistors, and the first MOS transistor M0, the third MOS transistor M4, the fourth MOS transistor M1, the sixth MOS transistor M5, the ninth MOS transistor M6 and the eighth MOS transistor M9 are enabling transistors, connected to the enabling signal. The second MOS transistor M2, the fifth MOS transistor M3, the seventh MOS transistor M7, and the tenth MOS transistor M8 are signal control transistors, connected to the first digital code. As shown in the figure, the second MOS transistor M2 is connected to the encoding signal B2, the fifth MOS transistor M3 is connected to the encoding signal B3, the seventh MOS transistor M7 is connected to the encoding signal B1, and the tenth MOS transistor M10 is connected to the encoding signal B3. The first NOT gate at the final end outputs the signal D1, and the second NOT gate outputs the signal D0, that is, the sixth signal and the fifth signal; wherein the signal D1 and the signal D0 are 2-bit signals. The truth table of the second-stage encoding circuit is shown in Table 1.

TABLE 1

| B3/B2/B1/B0 | Encoding Circuit Output D1/D0 |
|---|---|
| 0001 | 00 |
| 0010 | 01 |
| 0100 | 10 |
| 1000 | 11 |

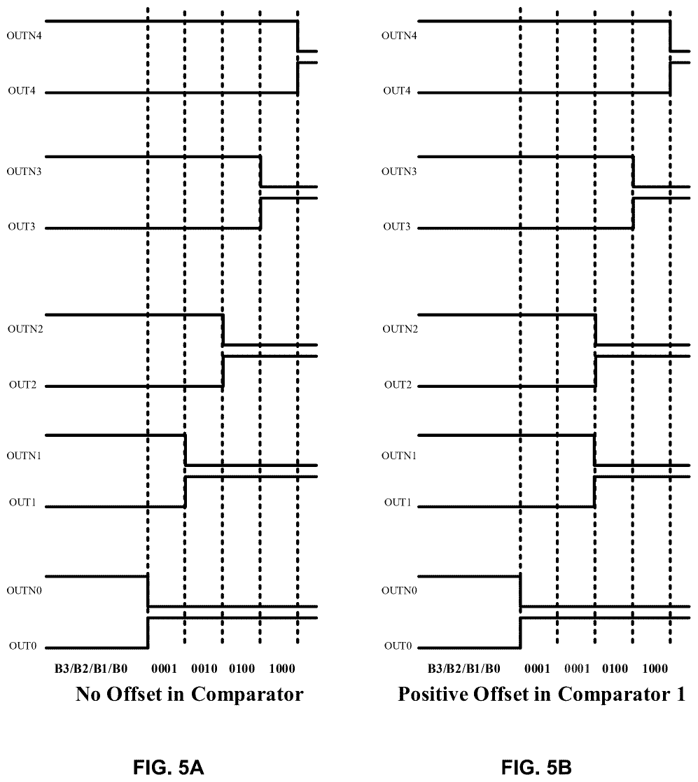

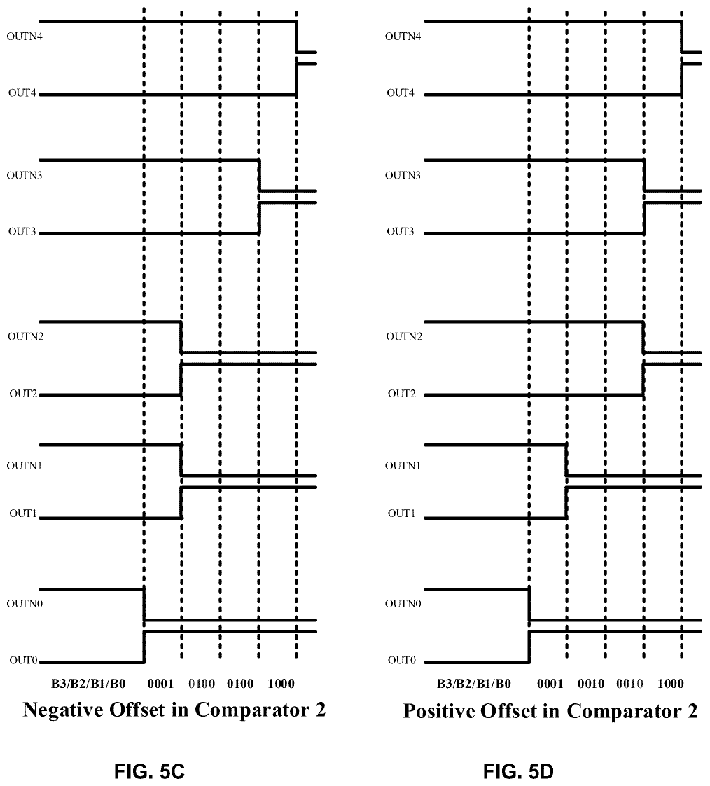

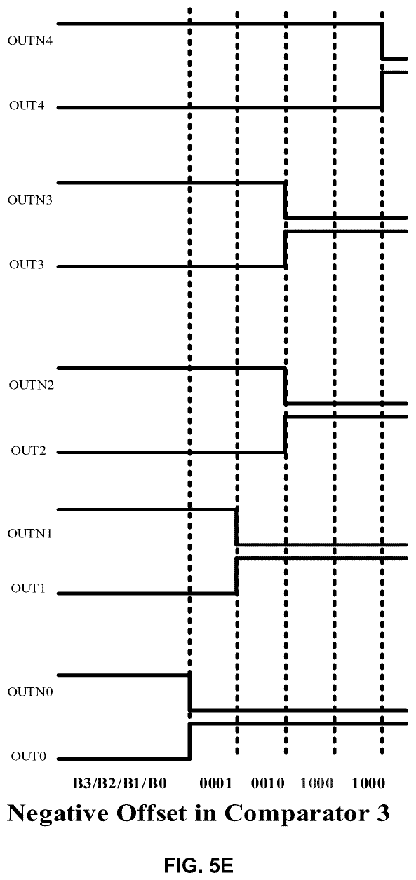

The principle of the encoding device is introduced below. As shown in FIG. 5A, when each comparator has no offset voltage, as the differential input signals VIP and VIN increase, the positive output end OUTi (i=0, 1, 2, 3, 4) of comparator 0 to comparator 4 gradually changes from a low level to a high level, and the negative output end OUTNi (i=0, 1, 2, 3, 4) of comparator 0 to comparator 4 gradually changes from a high level to a low level. At this time, assuming that the control signals S0 to S3 of the first selection module MUX in FIG. 4A are all low levels, the first selection module MUX selects the signal of the second input end A to output. It can be seen from the logical relationship in FIG. 4A that when comparator 0 to comparator 4 have no offset voltage, the output signal of each comparator is shown in FIG. 5A. As the input signal increases, the digital codes B0 to B3 will output 0001, 0010, 0100, and 1000 in sequence. If the input signal changes linearly, the probability of these four digital codes appearing is approximately the same. Assuming that only comparator 2 has a negative voltage at this time, as shown in FIG. 5B, when the input signal remains unchanged, the time for OUT2 to change from low level to high level will be advanced, the probability of digital code 0010 appearing will gradually decrease, and the occurrence of the original digital code 0010 will be gradually replaced by occurrence of the digital code 0100. Therefore, the probability of the occurrence of the digital code 0100 will gradually increase. Compared with the case where comparator 2 has no negative offset, the density changes of the three digital codes are that: 0001 density remains unchanged, 0010 density decreases, and 0100 density increases. As the negative offset of comparator 2 increases, making the threshold voltage of comparator 2 less than the threshold voltage of comparator 1, digital code 0010 will not appear at all, and the original digital code 0010 will be completely replaced by digital code 0100. At this time, the digital code that does not appear at all is 0010, and the digital codes on both sides are 0001 and 0100 respectively. Compared with the case where comparator 2 has no negative offset, the density changes of these three digital codes are as follows: the density of 0001 remains unchanged, the density of 0010 is 0, and the density of 0100 is about 2 times that of the case without offset. As can be seen from the previous description, when the threshold voltage of comparator 2 is less than the threshold voltage of comparator 1, the pipeline inter-stage redundancy technology cannot effectively correct the negative offset of comparator 2. At this time, additional correction is required for the negative offset voltage of comparator 2 that exceeds the correction range of the inter-stage redundancy technology.

When the threshold voltage of comparator 2 is less than the threshold voltage of comparator 1, the digital code that should be 0010 at this time is all changed to 0100. Therefore, if a part of the 0100 digital code is selected to be directly changed to 0010 through the digital circuit, a part of the 0010 digital code can be regained. There are two cases for the 0100 digital code selected for conversion. The first case is that if the selected 0100 digital code should be 0010 when there is no negative offset of comparator 2, it is necessary to compensate for the negative offset of comparator 2. The second case is that if the selected 0100 digital code is still 0100 when there is no negative offset of comparator 2, it is equivalent to introducing a positive offset to comparator 2, which increases the equivalent threshold voltage of comparator 2. However, under this correction idea, the digital code 0100 will still appear, which means that even if the equivalent threshold voltage of comparator 2 increases, its threshold voltage is still lower than the threshold voltage of comparator 3. Therefore, the forward offset voltage introduced by the correction will not make the equivalent threshold voltage of comparator 2 exceed the threshold voltage of comparator 3. At this time, the equivalent threshold voltage of comparator 2 is limited between the threshold voltages of comparator 1 and comparator 3, and the pipeline inter-stage redundancy technology can completely correct the forward offset introduced by the correction in comparator 2.

As shown in FIG. 4B, when the four digital codes 0001, 0010, 0100, and 1000 corresponding to Bi (I=0, 1, 2, 3) all appear, it means that the threshold voltage of the comparator is always between the threshold voltages of its adjacent comparators, and the output ENi (i=0, 1, 2, 3) of the code density judgment module is set to 0. At this time, the output digital code Bi (i=0, 1, 2, 3) in FIG. 4A is not corrected, and the offset voltage of the comparator can be corrected through the pipeline inter-stage redundancy technology. When the negative offset voltage of comparator 2 makes the threshold voltage of comparator 2 less than the threshold voltage of comparator 1, the code density of 0010 will be 0, and the code density judgment module will judge the adjacent digital code of the digital code 0010 with a code density of 0. There are two cases at this time. The first case is that the density of the code word 0001 lower adjacent to 0010 increases significantly, and the density of the code word 0100 upper adjacent to 0010 remains unchanged. At this time, it is explained that the phenomenon that the code density of 0010 is 0 is caused by the threshold voltage of comparator 1 exceeding the threshold voltage of comparator 2. The encoding relationship is shown in FIG. 5B. At this time, the correction method is to randomly invert the outputs of B0 and B1 in FIG. 4A, and set the outputs EN3 to EN0 of the code density judgment module in FIG. 4B to 0011, so that the outputs S3 to S0 of the MUX module in FIG. 4B are configured to 0011. Therefore, the corresponding MUX in FIG. 4A will randomly select the Q end and QN end of D flip-flop DFF at its previous stage, so that B1 and B0 in FIG. 4A are transformed from constant output 01 to random output 10 or 01, and finally the control of the equivalent threshold voltage of comparator 1 between comparator 0 and comparator 2 is realized. In the second case, the density of the code word 0001 lower adjacent to 0010 remains unchanged, and the density of the code word 0100 upper adjacent to 0010 increases significantly. At this time, it is explained that the phenomenon that the code density of 0010 is 0 is caused by the reduction of the threshold voltage of comparator 2, and its encoding relationship is shown in FIG. 5C. Therefore, the correction method is to randomly invert the outputs of B1 and B2 in FIG. 4A. At this time, the outputs EN3 to EN0 of the code density judgment module in FIG. 4B are set to 0110, so that the outputs S3 to S0 of the MUX module in FIG. 5B are configured to 0110. Therefore, the corresponding MUX in FIG. 4A will randomly select the Q end and QN end of its previous D flip-flop DFF, so that B2 and B1 in FIG. 4A change from constant output 10 to random output 10 or 01, and finally the control of the equivalent threshold voltage of comparator 2 between comparator 1 and comparator 3 is realized. According to the above rules, the truth table 2 of the code density judgment module is shown.

TABLE 2

| Encoding of B3/B2/B1/B0 | Encoding of |
|---|---|
| with 0 Code Density | EN3/EN2/EN1/EN0 |
| 0001 | 0001 |
| 0010 | 0011 |
| 0100 | 0110 |
| 1000 | 1100 |

From the description of the working principle of the above encoding circuit, it can be seen that when the code density of the four digital codes 0001, 0010, 0100, and 1000 corresponding to Bi (i=0, 1, 2, 3) is 0, it means that the threshold voltage of the corresponding comparator exceeds the threshold voltage interval of two adjacent comparators. Through the code density judgment module and random number generator in FIG. 4B, the equivalent threshold voltage of each comparator is controlled between its two adjacent comparators by using the digital correction method, and then the offset of the comparator is effectively corrected by the pipeline inter-stage redundant bit technology to ensure the final conversion accuracy. The above correction process is carried out from the low-order comparator to the high-order comparator, and the offset voltage of each comparator is corrected in turn, so that the equivalent threshold voltage of each comparator is between the threshold voltages of two adjacent comparators.

When the code density of 0010 in the four digital codes 0001, 0010, 0100, and 1000 corresponding to Bi (i=0, 1, 2, 3) is 0, the correction method is as follows. First, the code density judgment module is used to judge the reason for the code density being 0, i.e., whether it is caused by a negative offset in the comparator at this level or a positive offset in the adjacent low-order comparator; secondly, after the judgment is completed, the output signal ENi (i=0, 1, 2, 3) of the code density judgment module is used to control the positive and negative end signals of the two adjacent MUX random output D flip-flops DFF corresponding to FIG. 4A to generate a corrected digital signal Bi (i=0, 1, 2, 3); finally, a two-bit digital code is generated by the second encoding circuit shown in FIG. 4C. Similarly, when the code density of 0100 in the four digital codes 0001, 0010, 0100, and 1000 corresponding to Bi (i=0, 1, 2, 3) is 0, it is necessary to judge through the code density judgment circuit. If it is caused by the positive offset of comparator 2 (as shown in FIG. 5D), the code density output signals EN3 to EN0 need to be set to 0110 so that B2 and B1 in FIG. 4A randomly output high and low levels, and the equivalent threshold voltage of comparator 2 is controlled between the threshold voltages of comparator 1 and comparator 3. If it is caused by the negative offset of comparator 3 (as shown in FIG. 5E), the code density output signals EN3 to EN0 need to be set to 1100, so that B3 and B2 in FIG. 4A randomly output high and low levels, and the equivalent threshold voltage of comparator 3 is controlled between the threshold voltages of comparator 2 and comparator 4. The correction process for the remaining codes is similar.

In summary, the encoding device proposed in the present application does not need to specifically provide a comparator offset voltage correction mode, so that the ADC can realize the correction of the comparator offset voltage during normal operation, which simplifies the working timing of the circuit; at the same time, the present application adopts a digital domain correction method to correct the offset voltage of the flash ADC, and does not need to interact between the digital domain signal and the analog domain signal, thereby reducing the complexity of the layout routing and the introduction of non-ideal jitter and noise in the digital domain, and improving the accuracy of the circuit; and the present application removes the trimming capacitor at the input end of the comparator in the traditional structure, reduces the load of the sampling network, increases the input bandwidth, and reduces the circuit area and complexity.

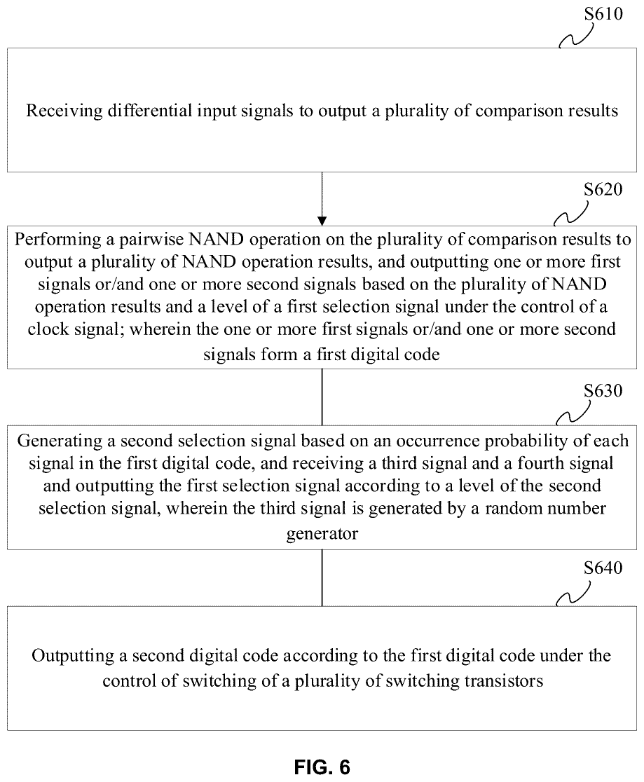

FIG. 6 is a flow chart of a method for encoding pipeline ADC according to an exemplary embodiment of the present application. As shown in FIG. 6, a method for encoding pipeline ADC includes:
step S610: receiving a differential input signal and outputting a plurality of comparison results;
step S620: performing a pairwise NAND operation on the plurality of comparison results to output a plurality of NAND operation results, and outputting one or more first signals or/and one or more second signals based on the plurality of NAND operation results and the level of the first selection signal under the control of the clock signal; wherein the one or more first signals or/and the one or more second signals constitute a first digital code;
step S630: generating a second selection signal based on the occurrence probability of each signal in the first digital code, and receiving a third signal and a fourth signal and outputting the first selection signal according to the level of the second selection signal, wherein the third signal is generated by a random number generator; and
step S640: outputting a second digital code according to the first digital code under the control of switching of a plurality of switching transistors.

It should be noted that the method for encoding pipeline ADC provided in the above embodiment and the device for encoding pipeline ADC provided in the above embodiment belong to the same concept, wherein the specific manner in which each module and unit performs operations has been described in detail in the device embodiment and will not be repeated here.

As described above, the device and the method for encoding pipeline ADC provided by the present application have the following beneficial effects.

The present application provides a device for encoding pipeline ADC, comprising: a comparator circuit, wherein an input end of the comparator circuit is connected to differential input signals and the comparator circuit outputs a plurality of comparison results; a first encoding circuit, connected to the comparator circuit, performing a pairwise NAND operation on the plurality of comparison results to output a plurality of NAND operation results, and outputting one or more first signals or/and one or more second signals based on the plurality of NAND operation results and a level of the first selection signal under the control of a clock signal; wherein the one or more first signals or/and the one or more second signals form a first digital code; an encoding control circuit, connected to an output end of the first encoding circuit, generating a second selection signal based on an occurrence probability of each signal in the first digital code, receiving a third signal and a fourth signal, and outputting the first selection signal according to a level of the second selection signal, wherein the third signal is generated by a random number generator; and a second encoding circuit, wherein an input end of the second encoding circuit is connected to an output end of the first encoding circuit, and the second encoding circuit outputs a second digital code according to the first digital code under a switch control of a plurality of switching transistors; the device for encoding proposed by the present application does not need to specifically provide a comparator offset voltage correction mode, so that the ADC can realize the correction of the comparator offset voltage in normal operation, simplifying the working timing of the circuit; in addition, the present application adopts a digital domain correction method to correct the offset voltage of the flash ADC without the need for interaction between digital domain signals and analog domain signals, thereby reducing the complexity of layout routing and the introduction of non-ideal jitter and noise in the digital domain, and improving the accuracy of the circuit; and the present application removes the trimming capacitor at the input end of the comparator in the traditional structure, reduces the load of the sampling network, increases the input bandwidth, and reduces the circuit area and complexity.

The encoding device proposed by the present application does not need to specifically provide a comparator offset voltage correction mode, so that the ADC can realize the correction of the comparator offset voltage during normal operation, thereby simplifying the working timing of the circuit.

The above embodiments are merely illustrative of the principles and effects of the present application, and are not intended to limit the present application. Anyone familiar with the technology may modify or change the above embodiments without violating the spirit and scope of the present application. Therefore, all equivalent modifications or changes made by a person of ordinary skill in the art without departing from the spirit and technical ideas disclosed in the present application shall still be covered by the claims of the present application.

What is claimed is:

1. A device for encoding pipeline ADC, comprising:
a comparator circuit, wherein an input end of the comparator circuit is connected to differential input signals and the comparator circuit is configured to output a plurality of comparison results;
a first encoding circuit, connected to the comparator circuit, configured to perform a pairwise NAND operation on the plurality of comparison results to output a plurality of NAND operation results, and output one or more first signals or/and one or more second signals based on the plurality of NAND operation results and a level of a first selection signal under a control of a clock signal; wherein the one or more first signals or/and the one or more second signals form a first digital code;
an encoding control circuit, connected to an output end of the first encoding circuit, configured to generate a second selection signal based on an occurrence probability of each signal in the first digital code, receive a third signal and a fourth signal, and output the first selection signal according to a level of the second selection signal, wherein the third signal is generated by a random number generator, the fourth signal is a preset level signal; and
a second encoding circuit, wherein an input end of the second encoding circuit is connected to the output end of the first encoding circuit, and the second encoding circuit is configured to output a second digital code according to the first digital code under a switch control of a plurality of switching transistors.

2. The device for encoding pipeline ADC according to claim 1, wherein the comparator circuit includes a plurality of comparators arranged in parallel, the first encoding circuit includes a plurality of encoding modules, each of the encoding modules includes:
a NAND gate, wherein input ends of the NAND gate are connected to the comparison results, and the comparison results are output through two adjacent output ends of two adjacent comparators, a first of the two adjacent output ends outputs a positive output signal, and a second of the two adjacent output ends outputs a negative output signal;
a D flip-flop, wherein a signal input end of the D flip-flop is connected to an output end of the NAND gate, and a first output end of the D flip-flop outputs the first signal, and a second output end of the D flip-flop outputs the second signal; and
a first selection module, wherein a first input end of the first selection module is connected to the first signal, a second input end of the first selection module is connected to the second signal, a control end of the first selection module is connected to the first selection signal, and the first selection module outputs the first signal or the second signal according to the level of the first selection signal.

3. The device for encoding pipeline ADC according to claim 2, wherein
when the first selection signal is at a high level, the first selection module uses the first signal as an output signal; and
when the first selection signal is at a low level, the first selection module uses the second signal as the output signal.

4. The device for encoding pipeline ADC according to claim 2, wherein the encoding control circuit includes:
the random number generator, configured to generate and output a random number sequence as the third signal;
a plurality of second selection modules, wherein input ends of the second selection modules are connected to an output end of the random number generator and connected to the third signal and the fourth signal, a control end of the second selection module is connected to the second selection signal, the second selection module outputs the first selection signal according to the level of the second selection signal; and
the plurality of second selection modules corresponds one to one with the plurality of first selection modules; and
a code density judgment module, wherein an input end of the code density judgment module is connected to an output end of the first selection module to receive the first digital code, and the code density judgment module outputs the second selection signal according to an occurrence probability of each signal in the first digital code.

5. The device for encoding pipeline ADC according to claim 4, wherein
when the second selection signal is at a high level, the second selection module uses the third signal as an output signal; and
when the second selection signal is at a low level, the second selection module uses the fourth signal as the output signal.

6. The device for encoding pipeline ADC according to claim 4, wherein the fourth signal is 0.

7. The device for encoding pipeline ADC according to claim 5, wherein the fourth signal is 0.

8. The device for encoding pipeline ADC according to claim 1, wherein the second encoding circuit includes:
a first encoding module, wherein an input end of the first encoding module is connected to the first digital code, and the first encoding module outputs a fifth signal according to the first digital code under a switch control of a plurality of switching transistors; and
a second encoding module, wherein an input end of the second encoding module is connected to the first digital code, and the second encoding module outputs a sixth signal according to the first digital code under a switch control of a plurality of switching transistors.

9. The device for encoding pipeline ADC according to claim 8, wherein
the first encoding module includes: a first MOS transistor, a second MOS transistor, a third MOS transistor, a fourth MOS transistor, a fifth MOS transistor, a first resistor, and a first NOT gate;
a source of the first MOS transistor is connected to a first voltage, a drain of the first MOS transistor is connected to a source of the second MOS transistor, a drain of the second MOS transistor is connected to a drain of the third MOS transistor and forms a first connection node, a source of the third MOS transistor is connected to a second voltage;
a source of the fourth MOS transistor is connected to the first voltage, a drain of the fourth MOS transistor is connected to a source of the fifth MOS transistor, a drain of the fifth MOS transistor, a first end of the first resistor, and an input end of the first NOT gate are respectively connected to the first connection node, a second end of the first resistor is connected to the second voltage, an output end of the first NOT gate outputs a fifth signal; and
a gate of the first MOS transistor, a gate of the third MOS transistor, and a gate of the fourth MOS transistor are respectively connected to an enable signal, and a gate of the second MOS transistor and a gate of the fifth MOS transistor are connected to the first digital code.

10. The device for encoding pipeline ADC according to claim 9, wherein
the second encoding module includes: a sixth MOS transistor, a seventh MOS transistor, an eighth MOS transistor, a ninth MOS transistor, a tenth MOS transistor, a second resistor, and a second NOT gate;
a source of the sixth MOS transistor is connected to the second voltage, a drain of the sixth MOS transistor is connected to a source of the seventh MOS transistor, a drain of the seventh MOS transistor is connected to a drain of the eighth MOS transistor and forms a second connection node, a source of the eighth MOS transistor is connected to the second voltage;
a source of the ninth MOS transistor is connected to the first voltage, a drain of the ninth MOS transistor is connected to a source of the tenth MOS transistor, a drain of the tenth MOS transistor, a first end of the second resistor, and an input end of the second NOT gate are respectively connected to the second connection node, a second end of the second resistor is connected to the second voltage, an output end of the second NOT gate outputs a sixth signal; and
a gate of the sixth MOS transistor, a gate of the eighth MOS transistor, and a gate of the ninth MOS transistor are respectively connected to an enable signal, and a gate of the seventh MOS transistor and a gate of the tenth MOS transistor are connected to the first digital code.

11. A method for encoding pipeline ADC, comprising:
receiving differential input signals to output a plurality of comparison results;
performing a pairwise NAND operation on the plurality of comparison results to output a plurality of NAND operation results, and outputting one or more first signals or/and one or more second signals based on the plurality of NAND operation results and a level of a first selection signal under a control of a clock signal; wherein the one or more first signals or/and the one or more second signals form a first digital code;
generating a second selection signal based on an occurrence probability of each signal in the first digital code, and receiving a third signal and a fourth signal and outputting the first selection signal according to a level of the second selection signal, wherein the third signal is generated by a random number generator; and
outputting a second digital code according to the first digital code under the control of switching of a plurality of switching transistors.
